(19) United States
(12) Patent Application Publication
(10) Pub. No.: US 2025/0155825 A1
(43) Pub. Date: May 15, 2025

(54) PHOTOLITHOGRAPHY RETICLE STAGE ACTUATORS

(71) Applicant: Massachusetts Institute of Technology, Cambridge, MA (US)

(72) Inventors: Charles Byron Seaberg, Wimberley, TX (US); David L. Trumper, Plaistow, NH (US)

(73) Assignee: Massachusetts Institute of Technology, Cambridge, MA (US)

(21) Appl. No.: 18/941,075

(22) Filed: Nov. 8, 2024

Related U.S. Application Data
(60) Provisional application No. 63/597,407, filed on Nov. 9, 2023.

(51) Int. Cl. G03F 7/00

(52) U.S. Cl. CPC G03F 7/70725; G03F 7/70758; G03F 7/70766; G03F 7/70775

(57) ABSTRACT

A photolithography system with an actuatable reticle stage is disclosed. Mechanical actuators coupled to a long-stroke reticle stage are driven to extend and mechanically contact a short-stroke stage during reticle stage turnaround. The actuators may be piezoelectric stack pushers or pneumatic bellows pushers. The pusher devices are controlled and driven to enable higher acceleration turnaround trajectories by applying forces via mechanical contact engaging during turnaround and disengaging before exposure begins during a scan.

### CROSS-REFERENCE TO RELATED APPLICATIONS

The present application claims priority to U.S. Provisional Patent Ser. No. 63/597,407, filed on Nov. 9, 2023, the content of which is hereby incorporated by reference in its entirety.

### STATEMENT REGARDING FEDERALLY SPONSORED RESEARCH

Not Applicable.

### FIELD OF TECHNOLOGY

The described technology generally relates to photolithography scanning tools, more particularly to systems and methods for actuating a reticle stage with high scan velocities and high acceleration turnaround trajectories.

### BACKGROUND

Photolithography is a step in the manufacturing of semiconductor chips. In photolithography, a photosensitive resist covering a silicon wafer is exposed to ultraviolet light in a design pattern which gives the chip its functionality. The pattern is created by modulating an exposure source with a reticle pattern such that the specified pattern of light is focused on the wafer. In modern photolithography scanners, only a slit of light is used to expose the wafer and the reticle and wafer are moved synchronously relative to the light source using actuators. Actuators must be capable of high forces to accelerate the reticle and wafer quickly, yet also maintain the precision required to adequately align the reticle and wafer during exposure.

Semiconductor photolithography requires the precise actuation of the reticle and wafer stages during the manufacture of integrated circuits. The wafer throughput of a scanning tool is bounded by the velocity and acceleration of the trajectories that the wafer and reticle follow. Maximizing tool throughput (i.e., minimizing manufacture time and maximizing the number of devices made) is an industry concern, given the widespread integration of semiconductors in commercial technologies and the potential of chip shortages. Additionally, reducing overall tool power consumption is important to reduce operating costs and meet sustainability objectives.

### SUMMARY

Aspects of the present disclosure provide for a photolithography system with an actuatable reticle stage. Mechanical actuators may be coupled to a long-stroke reticle stage and driven to extend and mechanically contact a short-stroke stage during reticle stage turnaround operations. The actuators may be piezoelectric stack pushers or pneumatic bellows pushers. The actuators are controlled and driven to enable higher acceleration turnaround trajectories by applying forces via intermittent mechanical contact engaging the short-stroke stage during scan and turnaround operations.

According to one aspect, a reticle stage system configured to support a photolithography reticle may include a drive system having at least one motor, a first stage coupled to the drive system, and a second stage coupled to the drive system. An array of pusher devices may be coupled to the second stage. A controller may be coupled to the drive system and the array of pusher devices. The controller may be adapted to drive intermittent mechanical contact of the array of pusher devices with the first stage.

The system may include, alone or in combination, one or more of the following features. The intermittent contact of the array of pusher devices with the first stage may reduce a relative velocity between the first stage and the second stage. The relative velocity may be reduced to substantially zero. The array of pusher devices may comprise piezoelectric pushers. The array of pusher devices may comprise metal bellows actuators. The array of pusher devices may include fluid-filled capsules with flexible diaphragms. The first stage may define one or more internal surfaces. The array of pusher devices may make the intermittent mechanical contact with the one or more internal surfaces. The first stage may be a short-stroke stage. The second stage may be a long-stroke stage. The intermittent mechanical contact of the array of pusher devices may provide a distributed force on the first stage during a turnaround operation. A scan actuator may be configured to position the first stage during a scan operation. The scan actuator may include one or more reluctance actuators.

According to another aspect, a method may include providing, in a reticle stage system, a first stage and a second stage coupled to a drive system having at least one motor. The second stage may be coupled to an array of pusher devices. The first stage and the second stage may be actuated during a scan operation in a first direction. The first stage may be engaged with the array of pusher devices. The motion of the first stage may be controlled with the array of pusher devices to reduce a relative velocity between the first stage and the second stage. The second stage may be driven in a second direction.

The method may include, alone or in combination, one or more of the following features. The array of pusher devices may be disengaged prior to a subsequent scan operation. The relative velocity may be reduced substantially zero. The array of pusher devices may comprise piezoelectric pushers. The array of pusher devices may comprise metal bellows actuators. The first stage may define one or more internal surfaces. The array of pusher devices may engage with the one or more internal surfaces. The engagement of the array of pusher devices may provide a distributed force about the first stage. A scan actuator may be configured to position the first stage during a scan operation. The scan actuator may include one or more reluctance actuators.

According to another aspect, a system may include a wafer stage configured to support a wafer during a photolithography operation and a reticle actuation system configured to support a reticle. The reticle actuation system may include a drive system having at least one motor, a first stage coupled to the drive system and a second stage coupled to the drive system. An array of pusher devices may be coupled to the second stage. A controller may be coupled to the drive system and the array of pusher devices and adapted to drive intermittent mechanical contact of the array of pusher devices with the first stage. An optical system may include an illumination source and at least one optical element configured to optically couple a signal from the illumination source to the reticle actuation system and the wafer stage during the photolithography operation.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, aspects of the present disclosure are illustrated by way of example and not limitation in the figures, in which.

FIG. 1 is a block diagram of a photolithography scanner system, according to one aspect of the disclosure.

FIG. 2 is a top-down view of a reticle stage system with paired pusher devices, according to one aspect of the disclosure.

FIG. 3 is a flow diagram illustrating the actuation of a pusher device, according to one aspect of the disclosure.

FIG. 4 is a diagram of a piezoelectric stack actuator, according to one aspect of the disclosure.

FIG. 5A is a top-down view of a partial reticle stage system with a non-actuated bellows pusher device, according to one aspect of the disclosure.

FIG. 5B is a top-down view of a partial reticle stage system with an actuated bellows pusher device, according to one aspect of the disclosure.

FIG. 6A is a top-down view of a reticle stage system, with the internal pusher devices, according to one aspect of the disclosure.

FIG. 6B is a sectional view of the reticle stage system of FIG. 6A, take across line A-A, according to one aspect of the disclosure.

FIG. 7 is a top-down view of an alternative reticle stage system having distributed pusher devices, according to one aspect of the disclosure.

FIG. 8 is a diagram of an example of a computing device, according to one or more aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for providing a thorough understanding of the various concepts. It will be apparent to those skilled in the art, however, that these concepts may be practiced without these specific details. In some instances, well-known structures and components are shown in block diagram form in order to avoid obscuring such concepts.

Modern photolithography scanners move a reticle along a scan axis at a constant velocity during exposure. The reticle moves back and forth repeatedly with this constant velocity, and during each scan, the pattern on the reticle may be transferred to the wafer in alternating directions.

Between scan exposures a turnaround operation is executed in which a large force is applied to the reticle stage with actuators. During turnaround, the wafer may be simultaneously repositioned to place a new field in the pathway for exposure. Minimization of reticle turnaround time may be desirable to increase machine throughput (e.g., wafers per hour).

According to one or more aspect of the present disclosure, pusher devices may be implemented on the reticle stage to increase the maximum acceleration and force capabilities of the stage. Turnaround actuators added to the reticle stage, however, should not create disturbance forces during the scan portion of the trajectory. Such forces may increase both the average and standard deviation of positional error during scan operations and may lead to a reduction in accuracy.

According to one aspect of the present disclosure, one way to minimize or eliminate disturbance forces during scan and turnaround operations is to apply forces using intermittent mechanical contact which may engage a short-stroke stage during a turnaround operation and disengage before exposure begins in a subsequent scan. In one aspect, actuators may apply a distributed force on the short-stroke stage to minimize the excitation of the reticle stage dynamics. As described herein, “distributed forces” may indicate that forces are applied at several locations on the body of the short-stroke stage.

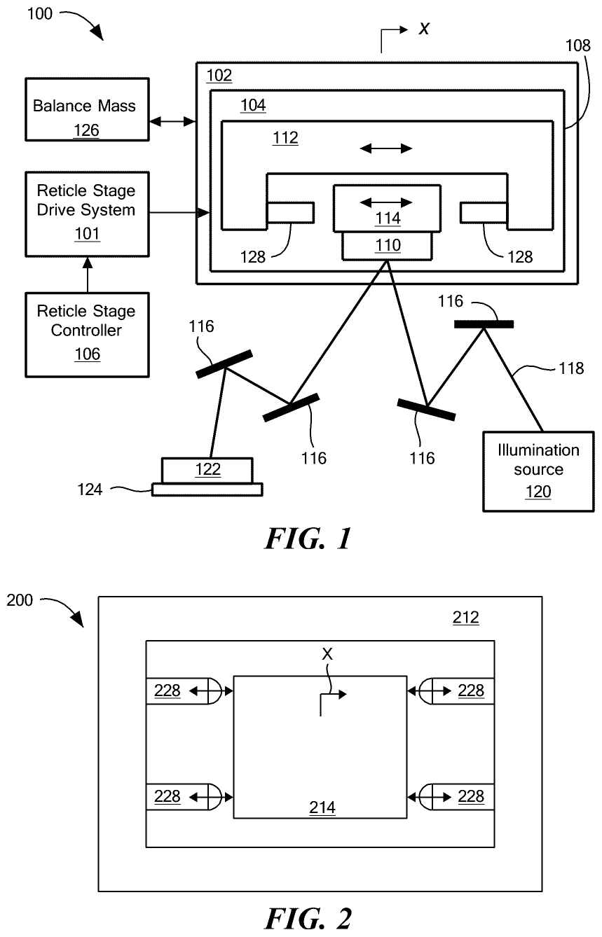

Referring now to FIG. 1, a photolithography system 100 may include a reticle actuation system 102 that may include a reticle stage drive system 101 coupled to a reticle stage 104. According to one aspect, the reticle stage drive system 101 may include a linear motor and may be used to magnetically levitate and move the reticle stage 104. Thus, the reticle actuation system 102 may operate such that in response to signals from a reticle stage controller 106, the reticle stage 104 may move during scan and turnaround operations.

Reticle stage 104 may be disposed in an enclosure 108. It should be noted that enclosure 108 may be coupled to a vacuum system (not explicitly shown in FIG. 1) capable of evacuating fluid (e.g., air) from enclosure 108. Thus, enclosure 108 may correspond to a vacuum chamber. It should also be appreciated that the reticle stage 104 may move within a vacuum environment. Furthermore, in the case where the photolithography system 100 is a next-generation photolithography system (e.g., an extreme ultraviolet (EUV) system) then the reticle stage 104 may move in an ultra-clean high-vacuum environment, as would be readily understood by one skilled in the art.

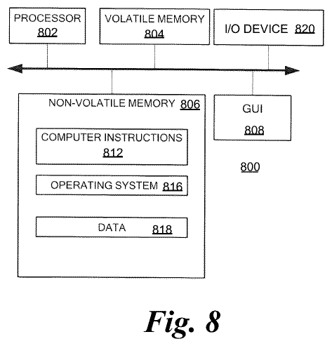

Reticle stage controller 106 may issue control signals or commands to control movement of the reticle stage 104. The reticle stage controller 106 may include, for example, control circuitry and software which provides signals to initiate movement (e.g., position reference signals profiles) of reticle stage 104 between one or more positions. The reticle stage controller may be, or may include, a computing device such as the computing device 800 described in connection with FIG. 8. The reticle stage controller 106 may also be capable of performing real-time control for motion and magnetic suspensions of the reticle stage 104. That is, the reticle stage controller 106 may include having an active control capability, which may read sensor signals and send controlling commands to drive the actuators for the reticle stage 104, as described herein.

The reticle stage 104 may include a long-stroke stage 112 and short-stroke stage 114, to which a reticle 110 is clamped. The long-stroke stage 112 may have a larger travel and follow the reticle trajectory within several micrometers. The short-stroke stage 114 may be restricted to remain within about ±0.5 millimeters (mm) of the long-stroke stage 112 but is intended to follow the reticle trajectory with sub-nanometer error. According to one aspect, to achieve the required accuracy and precision, the short-stroke stage 114 may be magnetically levitated and controlled in six degrees-of-freedom (DOF) using scan actuators (not shown) mounted to the long-stroke stage 112 with corresponding components on the short-stroke stage 114.

The reticle stage drive system 101 of the reticle actuation system 102 may be capable of moving the reticle 110 during scan and turnaround operations. According to one aspect of the disclosure, an array of pusher devices, such as pushers 128, may be mounted to the long-stroke stage 112 and may be passive or may be driven by the reticle stage drive system 101 to extend and mechanically contact the short-stroke stage 114 during turnaround operations. According to one aspect, the pushers 128 may be one or more of piezoelectric stack actuators and/or metal bellows actuators, as described in greater detail below. The pushers 128 may further be or include fluid-filled capsules with flexible diaphragms. The pushers 128 described herein may enable higher acceleration turnaround trajectories by applying forces via intermittent mechanical contact between the long-stroke stage and the short-stroke stage which engages during turnaround operations and disengages before exposure begins in a subsequent scan operation. Disengagement before subsequent scan exposure may be needed to eliminate the transmission of a disturbance force to the short-stroke stage due to the positional error of the long-stroke stage via the mechanical stiffness of the pusher device.

In operation, the reticle 110 may be disposed in a vacuum chamber which contains optical elements 116 which may reflect or otherwise direct a signal 118 (e.g., a light or laser signal) from an illumination source 120 toward a substrate, such as a wafer 122. The wafer 122 may be disposed on a moveable wafer stage 124. During a scan operation, the illumination source 120 may transmit the signal 118 through the optical elements 116, through the reticle 110 so as to produce a desired pattern on the wafer 122. It should be appreciated that not all of the elements in the photolithography system 100 are shown in FIG. 1. For simplicity and to promote clarity in FIG. 1, some conventional components necessary to use and direct light to transfer a desired geometric pattern from the reticle to a substrate have not been shown in FIG. 1, however such elements and their functionality would be well-understood by a person skilled in the art. While the optical paths drawn in FIG. 1 are reflective, optical elements may also be transmissive like those commonly used in DUV tools.

The reticle stage 104 may be coupled to a balance mass 126 to avoid transmission of reaction forces into the frame of the photolithography system 100 when the reticle stage 104 is in motion.

While the photolithography system 100 and its exemplary optics depicted in FIG. 1 may be configured for extreme ultraviolet lithography (EUV), one skilled in the art will recognize that the concepts, systems, and methods described herein may also be implemented in a deep ultraviolet (DUV) tool without deviating from the scope of the present disclosure.

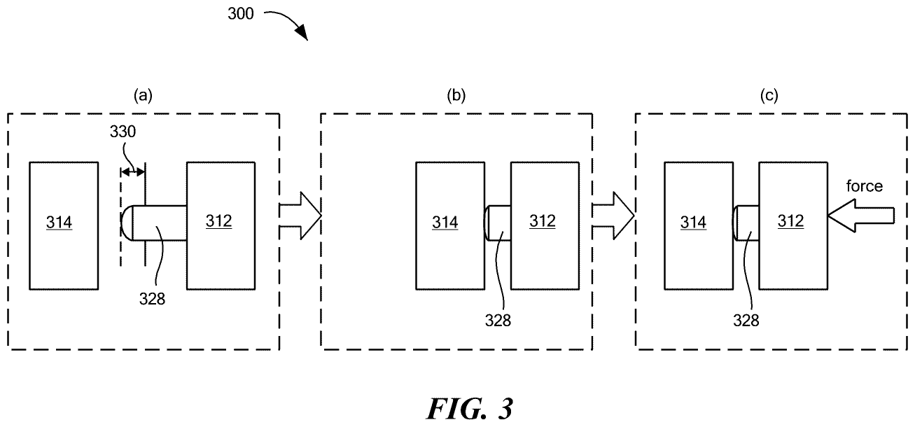

FIG. 2 depicts a top-down view of a reticle stage 200 according to one aspect of the present disclosure. An array of pushers 228 may be mounted to a long-stroke stage 212 and may be driven to extend and mechanically contact a short-stroke stage 214 and transfer forces for high acceleration reticle turnaround without exciting the dynamics of the stage. Alternatively, the pusher actuators may be passive, and the contact between the array of pushers 228 and short-stroke-stage 214 may be established by actuating the long-stroke linear motor (not shown) and short-stroke scan actuators (not shown). Pusher devices with high force density and low mass may reduce the overall mass of the short-stroke stage, and thereby reduce the mechanical power required to perform a scanning operation. In addition, pusher devices with high energy efficiency may reduce the power dissipation required for short-stroke actuation. According to one aspect, the array may include four pushers 228. Since the pushers 228 may be only capable of a pushing force via mechanical contact, at minimum, a pair of pushers 228 may be implemented to provide bidirectional forces in the scan axis, denoted by arrow ‘x’.

According to one aspect, the pushers 228 may be actuated to manage intermittent contact with the short-stroke stage 214. Doing so may begin with the pushers 228 extending to a maximum extension. At that time, scan actuators and/or long-stroke actuators (distinct from the pusher actuators 228) may be driven such that the short-stroke stage 214 and long-stroke stage 212 have a relative velocity which begins to close a gap between the short-stroke stage 214 and the pushers 228. According to one aspect, the closing of the gap (e.g., drift) may begin during the scan operation to reduce the time required to close the gap and thereby decrease the total turnaround time. When the short-stroke stage 214 contacts the pushers 228, the pushers 228 may be driven to retract and bring the short-stroke stage 214 and the long-stroke stage 212 to the same velocity while avoiding the excitation of stage dynamics. The long-stroke actuators (not shown) may begin to accelerate the long-stroke stage 212 as force from the long-stroke actuators is transferred to the short-stroke stage 214 via the array of pushers 228.

According to one aspect, the pushers 228 may instead be passively designed to manage intermittent contact with the short-stroke stage 214 without actuation. In this configuration, scan actuators and/or long-stroke actuators (distinct from the pusher actuators 228) may be driven such that the short-stroke stage 214 and long-stroke stage 212 have a relative velocity which begins to close a gap between the short-stroke stage 214 and the pushers 228. According to one aspect, the closing of the gap (e.g., drift) may begin during the scan operation to reduce the time required to close the gap and thereby decrease the total turnaround time. When the short-stroke stage 214 contacts the pushers 228, the pushers 228 may begin to compress and through passive dynamics bring the short-stroke stage 214 and the long-stroke stage 212 to the same velocity while avoiding the excitation of stage dynamics. The long-stroke actuators (not shown) may begin to accelerate the long-stroke stage 212 as force from the long-stroke actuators is transferred to the short-stroke stage 214 via the array of pushers 228.

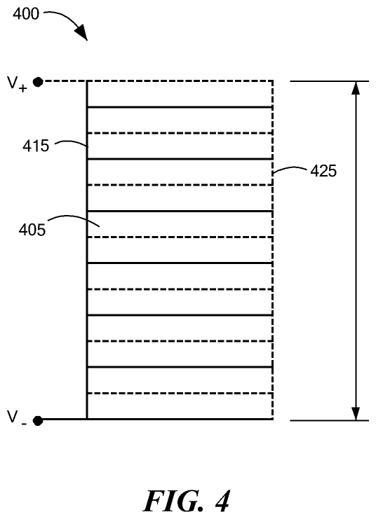

FIG. 3 is a flow diagram illustrating, in part, the reticle stage actuation process 300 during a turnaround operation, according to one aspect of the disclosure. At or near the end of a scan operation, as shown in block (a), the pusher(s) 328 may extend 330 while a short-stroke stage 314 drifts towards a long-stroke stage 312. For the sake of clarity and brevity, only one pusher 328 is shown, however one skilled in the art will recognize that the actuation of the other pushers may be accomplished in substantially the same manner as shown and described herein.

As shown in block (b), the pusher 328 may mechanically engage or contact the short-stroke stage 314 and provide a pushing force to bring the long-stroke stage 312 and the short-stroke stage 314 to about zero relative velocity. As shown in block (c), a long-stroke motor, for example a linear drive motor, may start to accelerate the long-stroke stage 312 to a turnaround force of about 100 g, for example. The force may be transferred to the short-stroke stage 314 with the pushers 328 such that the short-stroke state 314 and the long-stroke stage 312 move in the turnaround operation with about zero relative velocity between the two stages.

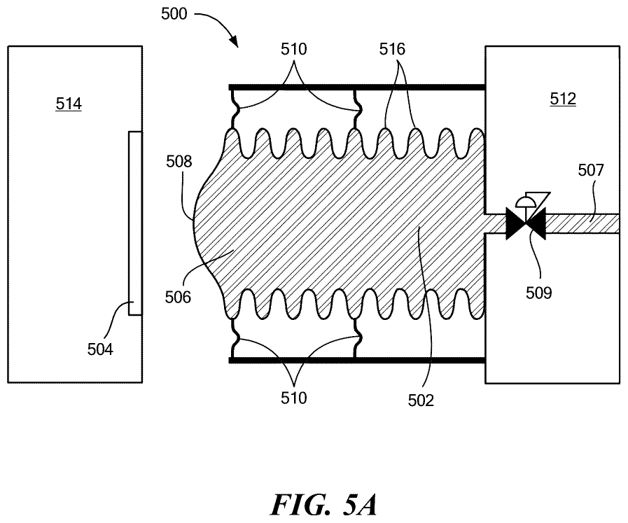

According to one aspect, the pusher actuators, like pushers 328, may include or be formed from linear piezoelectric stack actuators. FIG. 4 shows a diagram of an exemplary stack actuator 400 in which multiple layers of piezoelectric material 405 may be positioned between electrode plates 415, 425. The electrode plates 415, 425 may be used to apply an electric potential (V₊, V₋) across the piezoelectric material 405. The actuator may operate according to a piezoelectric effect in which the application of the electric field to the piezoelectric material 405 may cause a mechanical stress in the material. If unrestricted, the stress may result in actuator strain creating lengthening motion at the face of the actuator. If the piezoelectric material 405 is mechanically restrained, the stress may result in a force applied to the restraints which oppose the strain.

According to one aspect, using piezoelectric stack actuators 400 as pushers may provide high bandwidth control and high actuator force capability. Depending on the required pusher stroke, such pushers can be or have a relatively low volume. In addition, the piezoelectric stack actuators 400 may be reliable and typically rated for billions of cycles under normal operating conditions. For use in EUV tools, according to one aspect, vacuum compatible versions of piezoelectric pushers may be utilized. In addition to serving as actuators, in one aspect, such piezoelectric stacks 400 also may be used as sensors since compression of the piezoelectric stacks may result in a measurable change in charge with associated transient currents.

Piezoelectric materials may be only capable of extending to approximately 0.1% strain. Thus, for example, an actuator stack with a 50 mm length may have a travel of only about 50 μm. Packaging multiple pusher actuators of this length to push on internal faces of the short-stroke stage, may present challenges. As the pusher length increases, the stiffness and resonant frequency of the pusher may decrease. A high resonant frequency of the pusher actuators may be desirable to control the dynamics of the stage, thus allowing the length of the pusher to be reduced.

Actuator total force capability may be proportional to the cross-sectional area of the piezoelectric material. Thus, as the diameter of the piezoelectric stack actuator 400 increases, the maximum force from the pusher may increase. However, larger stack diameters also may result in increased pusher capacitance and require more current from driving amplifiers.

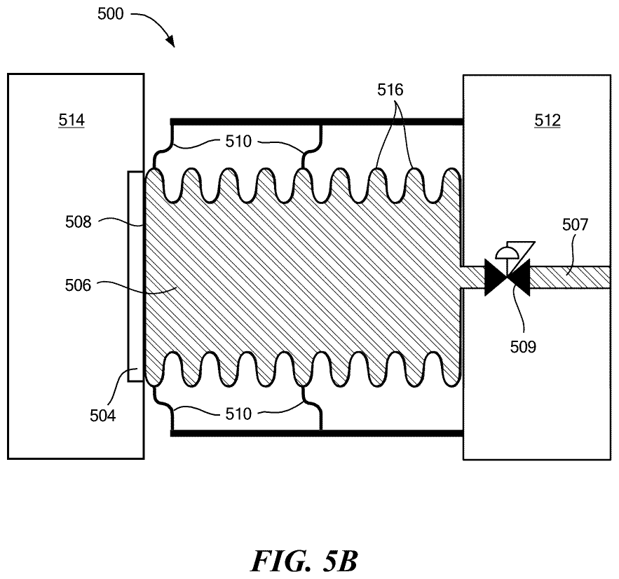

Turning now to FIGS. 5A-5B, according to one aspect of the disclosure, actuator pushers may be formed from or include a thin-walled metal bellows actuator. FIG. 5A shows a pusher 500 including a metal bellows actuator 502 mounted to a long-stroke stage 512 and internally pressurized to extend and retract. According to one aspect, the internal pressure of the bellows 502 may be controlled to extend the pusher 500 into mechanical contact with the short-stroke stage 514. The bellows 502 may either be pressurized with either a gas, such as air or hydrogen, or a liquid, such as water, supplied from a fluid supply 507 and controlled by a valve 509. The bellows actuator 502 may be manufactured from a number of materials including, for example, hardenable or austenitic stainless steel. The side walls of the bellows 502 may include or form a single layer with multiple corrugations 516 along the length of the side wall. Rolling cylindrical flexures 510 may externally support the bellows 502, for example, to prevent a buckling failure.

The pusher 500 may be driven to contact a contact patch 504 formed from a material attached to the short-stroke stage 514 during turnaround. According to one aspect, the tip 506 of the bellows 502 may be rounded to have a defined contact point with low inertia which may decrease the impulse of force on the short-stroke stage 514 associated with initial contact. Due to the initially bowed shape, the initial stiffness required to compress the diaphragm of the bellows 502 after contact may also be low due to the small pressurized cross sectional area in contact. This area will increase resulting in a higher stiffness under further compression. The rounded shape may occur due to the internal pressure acting on the end wall 508 of the bellows 502. According to one aspect, the end wall 508 may be or include a flexible diaphragm composed of a metal or other material. The bellows end wall 508 may contact the short-stroke stage 514 deterministically with a round-on-flat contact. According to an alternative aspect, a flexible diaphragm composed of metal or other material may be integrated into a pressurized capsule without bellows. In this case, the deformation of the flexible diaphragm due to internal pressure may constitute the entire stroke of the pusher capsule. The pressure inside the capsule may be actively controlled or set to an initial bias pressure. The geometry inside the capsule may be passively designed to couple diaphragm deformation to internal pressure and achieve a pusher device with a favorable dynamic stiffness.

FIG. 5B shows the pusher 500 extended and engaged with the short-stroke stage 514. The bellows 502 may be pressurized to extend into and engage the contact patch 504 of the short-stroke stage 514.

According to one aspect, the pusher actuators may be designed to create lateral compliance (i.e., flexibility in the axis normal to the expansion direction) so as to not overconstrain the contact surface and allow for relative movement of the short-stroke stage 514 and long-stroke stage 512 normal to the contact patch 504. Overconstraint may lead to an increase in frictional scrubbing forces at the contact patch 504 and increased wear and particle generation on the contact surfaces.

To address overconstraint, according to one aspect, the contact patch 504 on the short-stroke stage 514 may be made out of a composite structure consisting of sheets of elastomers between rigid plates. Elastomers, such as rubber, may be stiff in compression but compliant in shear. There may also be some lateral compliance in the bellows 502 itself. The lateral compliance, however, can cause pusher failure via column buckling. As such, guiding flexures 510 may be added for stability.

According to one aspect, a pneumatic pusher, like bellows pusher 500, may have the ability to decouple the actuator force from movement of the long-stroke stage 512 via a pressure constraint. The force applied to the short-stroke stage 514 from a bellows pusher 500, with cross-section area A and pressure P, may be given as:

$$F = P A \qquad ( 1 )$$

In equation (1), the inherent stiffness of the bellows pusher 500 is assumed to be negligible. In reality, the deflection of the bellow's metal corrugations 516 may create a mechanical stiffness that couples actuator elongation with pushing force. Assuming the actuator force is governed by Equation (1), if a constant pressure is maintained, the force may be constant irrespective of long-stroke position and thus zero stiffness. For a similar reason, Lorentz actuators are often used in precision control applications since the ideal Lorentz force is purely proportional to coil current. However, for a finite gas volume, gas pressure will change as a function of volume. In a sealed volume actuator, with ideal gas behavior and constant temperature, the relationship between pressure and volume in two equilibrium states may be given as:

$$PV = {P}_{0} {V}_{0} \qquad ( 2 )$$

where, P₀ is the original pressure and V₀ is the original volume. The volume of the second state may defined in terms of the original volume plus a small change as:

$$V = {V}_{0} + Δ V \qquad ( 3 )$$

and the pressure of the second state in terms of the original pressure plus the change as

$$P = {P}_{0} + Δ P \qquad ( 4 )$$

then the change in pressure due to a change in gas volume is:

$$Δ P = {P}_{0} \frac{Δ V}{{V}_{0} + Δ V} \qquad ( 5 )$$

According to one aspect, a larger volume will have a smaller change in pressure for a given change in volume. Further, by assuming constant cross-sectional area, we can define pusher volume based on pusher length as:

$$V = A x \qquad ( 6 )$$

Equation (5) may be written in terms of the change in force as a function of linear displacement as:

$$Δ F = {F}_{0} \frac{Δ x}{{x}_{0} + Δ x} \qquad ( 7 )$$

If the actuator length is assumed to be significantly longer than the change in length due to positional error of the long-stroke stage (x₀>>Δx), then Equation (7) simplifies to:

$$Δ F = \frac{{F}_{0}}{{x}_{0}} Δ x \qquad ( 8 )$$

Using Equation (8), if it is assumed that the bellows actuator has a length of 100 mm and nominal force of 10 kilonewtons (kN), then the change in force caused by a 10 μm RMS positional error in the long-stroke stage during turnaround would result in 1 N RMS error in actuator force.

When comparing this result to a stiff connection, such as that of an array of piezoelectric actuators with parallel stiffness k=100 N/μm, the change in force due to a change in actuator displacement may be

$$Δ F = k Δ x \qquad ( 9 )$$

In such a case, the same 10 μm RMS positional error in the long-stroke stage during turnaround may result in 1 kN RMS error in actuator force. The actuator force in the piezoelectric pusher system may be up to one thousand times more sensitive to long stroke positional noise than a pneumatic pusher. In the case of the piezoelectric pusher, active control may be used to ensure transient forces of this magnitude are not translated to the short-stroke stage. On the other hand, the low force sensitivity of the pneumatic pusher may be inherent to the actuator's governing pressure constraint. This may provide one advantage of the pneumatic pusher in decoupling the actuator force from the dynamics of the long-stroke stage.

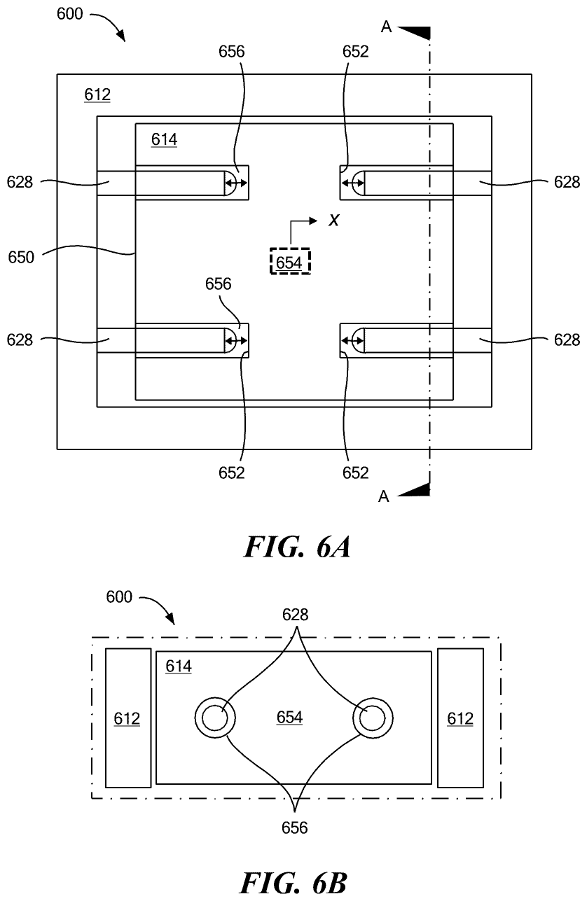

Turning now to FIGS. 6A-B, an alternative pusher actuator packaging 600 may include four pusher actuators 628 mounted to a long-stroke stage 612 and having lengths extending into the short-stroke stage 614. FIG. 6A is a top-down view, while FIG. 6B is a sectional view taken across line A-A. According to one aspect, the four pusher actuators 628 with longer initial length, such as the piezoelectric stack actuators described herein, may be packaged by forming cavities 656 in the short-stroke stage 614. Such a configuration may move the pusher force from the outer edges 650 of the short-stroke stage 614 to internal surfaces 652 near the stage's center of mass 654. According to one aspect, moving the pusher force inward may be advantageous for preventing excitation of the first oscillatory mode of the short stroke in the scan direction, x. According to one aspect, the cavities 656 may be sized and shaped to provide sufficient clearance between the pusher actuators 628 and the short-stroke stage 614 to accommodate any translation and/or rotation in the non-scan axis.

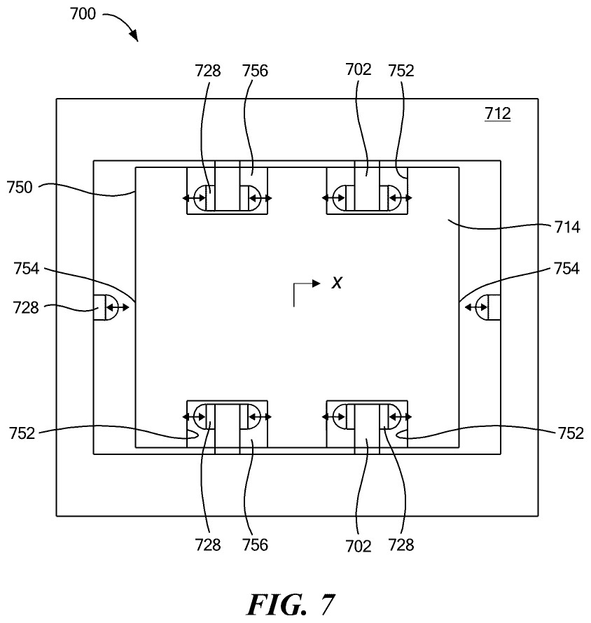

Turning now to FIG. 7, another alternative packaging 700 may be provided to increase the distribution of force about a short-stroke stage 714. According to one aspect, up to ten pusher actuators 728 may be mounted to the long-stroke stage 712. The long-stroke stage 712 may include projections 702 extending into cavities 756 formed around the exterior perimeter 750 of the short-stroke stage 714. The pusher actuators 728 may be cantilevered from the long-stroke stage 712 to provide forces on the short-stroke stage 714 at internal surfaces 752 within the cavities 756 and external surfaces 754 along the scan direction.

According to another aspect of the present disclosure, generally, actuation of the short-stroke stage may be accomplished with scan actuators mounted to the short-stroke stage with counterparts mounted to the long-stroke stage. The force generation mechanism for these scan actuators may be electromagnetic, such as Lorentz or reluctance actuators. Since the proposed pusher devices are not in contact during scan exposure, scan actuators may be used to position the short-stroke stage during scan exposure. In addition, these actuators may be used during turnaround to control the relative position of the short-stroke and long-stroke stages, including engaging and disengaging mechanical contact of the short-stroke stage with the pusher devices. However, the maximum sustained force capability of such scan actuators may not exceed that of the pusher devices.

Referring to FIG. 8, in some embodiments, a computing device 800, such as a controller, driver, or the like, may include processor 802, volatile memory 804 (e.g., RAM), non-volatile memory 806 (e.g., a hard disk drive, a solid-state drive such as a flash drive, a hybrid magnetic and solid-state drive, etc.), graphical user interface (GUI) 808 (e.g., a touchscreen, a display, and so forth) and input/output (I/O) device 820 (e.g., a mouse, a keyboard, etc.). Non-volatile memory 806 stores computer instructions 812, an operating system 816 and data 818 such that, for example, the computer instructions 812 are executed by the processor 802 out of volatile memory 804. Program code may be applied to data entered using an input device of GUI 808 or received from I/O device 820.

Based on the teachings, one skilled in the art should appreciate that the scope of the present disclosure is intended to cover any aspect of the present disclosure, whether implemented independently of or combined with any other aspect of the present disclosure. For example, an apparatus may be implemented, or a method may be practiced using any number of the aspects set forth. In addition, the scope of the present disclosure is intended to cover such an apparatus or method practiced using other structure, functionality, or structure and functionality in addition to, or other than the various aspects of the present disclosure set forth. It should be understood that any aspect of the present disclosure may be embodied by one or more elements of a claim.

Although reference is made herein to particular materials, it is appreciated that other materials having similar functional and/or structural properties may be substituted where appropriate, and that a person having ordinary skill in the art would understand how to select such materials and incorporate them into embodiments of the concepts, techniques, and structures set forth herein without deviating from the scope of those teachings.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

As used herein, the term “determining” encompasses a wide variety of actions. For example, “determining” may include calculating, computing, processing, deriving, investigating, looking up (e.g., looking up in a table, a database or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

The various illustrative logical blocks, modules and circuits described in connection with the present disclosure may be implemented or performed with a processor specially configured to perform the functions discussed in the present disclosure. The processor may be a neural network processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described herein. Alternatively, the processing system may comprise one or more neuromorphic processors for implementing the neuron models and models of neural systems described herein. The processor may be a microprocessor, controller, microcontroller, or state machine specially configured as described herein. A processor may also be implemented as a combination of computing devices, e.g., a combination of a DSP and a microprocessor, a plurality of microprocessors, one or more microprocessors in conjunction with a DSP core, or such other special configuration, as described herein.

The steps of a method or algorithm described in connection with the present disclosure may be embodied directly in hardware, in a software module executed by a processor, or in a combination of the two. A software module may reside in storage or machine readable medium, including random access memory (RAM), read only memory (ROM), flash memory, erasable programmable read-only memory (EPROM), electrically erasable programmable read-only memory (EEPROM), registers, a hard disk, a removable disk, a CD-ROM or other optical disk storage, magnetic disk storage or other magnetic storage devices, or any other medium that can be used to carry or store desired program code in the form of instructions or data structures and that can be accessed by a computing system. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The controllers and processors may be responsible for managing the bus and processing, including the execution of software stored on the machine-readable media. Software shall be construed to mean instructions, data, or any combination thereof, whether referred to as software, firmware, middleware, microcode, hardware description language, or otherwise.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or specialized register files. Although the various components discussed may be described as having a specific location, such as a local component, they may also be configured in various ways, such as certain components being configured as part of a distributed computing system.

The machine-readable media may comprise a number of software modules. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a special purpose register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any storage medium that facilitates transfer of a computer program from one place to another.

Further, it should be appreciated that modules and/or other appropriate means for performing the methods and techniques described herein can be downloaded and/or otherwise obtained by a user terminal and/or base station as applicable. For example, such a device can be coupled to a server to facilitate the transfer of means for performing the methods described herein. Alternatively, various methods described herein can be provided via storage means, such that a user terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A reticle stage system configured to support a photolithography reticle, the reticle stage system comprising:
a drive system having at least one motor;
a first stage coupled to the drive system;
a second stage coupled to the drive system;
an array of pusher devices coupled to the second stage; and
a controller coupled to the drive system and the array of pusher devices, the controller adapted to drive intermittent mechanical contact of the array of pusher devices with the first stage.

2. The reticle stage system of claim 1 wherein the intermittent mechanical contact of the array of pusher devices with the first stage reduces a relative velocity between the first stage and the second stage.

3. The reticle stage system of claim 2 wherein the relative velocity is reduced to substantially zero.

4. The reticle stage system of claim 1 wherein the array of pusher devices comprises piezoelectric pusher actuators.

5. The reticle stage system of claim 1 wherein the array of pusher devices comprises metal bellows actuators.

6. The reticle stage system of claim 1 wherein the array of pusher devices comprises fluid-filled capsules with flexible diaphragms.

7. The reticle stage system of claim 1 wherein the first stage defines one or more internal surfaces, the array of pusher devices making the intermittent mechanical contact with the one or more internal surfaces.

8. The reticle stage system of claim 1 wherein the first stage is a short-stroke stage.

9. The reticle stage system of claim 1 wherein the second stage is a long-stroke stage.

10. The reticle stage system of claim 1 wherein the intermittent mechanical contact of the array of pusher devices provides a distributed force on the first stage during a turnaround operation.

11. The reticle stage system of claim 1 further comprising a scan actuator configured to position the first stage during a scan operation.

12. The reticle stage system of claim 11 wherein the scan actuator includes one or more reluctance actuators.

13. A method comprising:
providing, in a reticle stage system, a first stage and a second stage coupled to a drive system having at least one motor, the second stage coupled to an array of pusher devices;
actuating the first stage and the second stage during a scan operation in a first direction;
engaging the first stage with the array of pusher devices;
controlling the motion of the first stage with the array of pusher devices to reduce a relative velocity between the first stage and the second stage; and
driving the second stage in a second direction.

14. The method of claim 13 further comprising disengaging the array of pusher devices prior to a subsequent scan exposure.

15. The method of claim 13 wherein the array of pusher devices comprises piezoelectric pushers.

16. The method of claim 13 wherein the array of pusher devices comprises metal bellows actuators.

17. The method of claim 13 wherein the first stage defines one or more internal surfaces, the array of pusher devices engaging with the one or more internal surfaces.

18. The method of claim 13 wherein the engagement of the array of pusher devices provides a distributed force about the first stage.

19. The method of claim 13 further comprising a scan actuator configured to position the first stage during a scan operation, the scan actuator including one or more reluctance actuators.

20. A system comprising:
a wafer stage configured to support a wafer during a photolithography operation;
a reticle actuation system configured to support a reticle, the reticle actuation system including;
a drive system having at least one motor;
a first stage coupled to the drive system;
a second stage coupled to the drive system;
an array of pusher devices coupled to the second stage; and
a controller coupled to the drive system and the array of pusher devices, the controller adapted to drive intermittent mechanical contact of the array of pusher devices with the first stage; and
an optical system including an illumination source and at least one optical element configured to optically couple a signal from the illumination source to the reticle actuation system and the wafer stage during the photolithography operation.
